(19) United States
(12) Patent Application Publication
(10) Pub. No.: US 2004/0146124 A1
(43) Pub. Date: Jul. 29, 2004

(54) ALGORITHM FOR TIMING RECOVERY IN A FSK CORRELATION RECEIVER AND FSK CORRELATION RECEIVER THEREWITH

(76) Inventor: DAVID SHIUNG, TAINAN (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/248,498

(22) Filed: Jan. 24, 2003

(51) Int. Cl. H04L 27/14; H03D 3/00

(52) U.S. Cl. 375/334

(57) ABSTRACT

An algorithm for time recovery in a digital frequency shift keying (FSK) receiver. The receiver correlated a training sequence with predetermined reference signals to generate corresponding correlation values. According to the generated correlation values, status of timing in the FSK receiver is determined. If the FSK receiver is in a timing-inaccurate status, an adjustment for the timing of the FSK receiver is determined in according to the correlation value.

### BACKGROUND OF INVENTION

1. Field of Invention

The present invention relates to an algorithm for timing recovery for a digitalfrequency shift keying (FSK) correlation receiver and a FSK correlation receiver therewith. More particularly, the present invention relates to an algorithm for timing recovery for a digital FSK correlation receiver and a FSK correlation receiver therewith, in which a training sequence with a bit pattern is used for correlation and an adjustment is determined for timing recovery therefrom.

2. Description of Related Art

As wireless technology revolutionizes the world, different products covering a wide-range cost are developed to satisfy consumers' need. Digital frequency shift keying (FSK) is frequently used in wireless systems for its performance and well-known technology. In any conventional FSK correlation receiver, there must be an external synchronization and a timing recovery circuit for bit synchronization, clock recovery and timing recovery respectively. The external timing recovery circuitry is complicated involving multiple logical, judging, and sampling circuits that are high in cost to manufacture. Prior art uses various well-known timing recovery methods such as open-loop timing recovery, spectral-line timing recovery, squaring timing recovery, zero-crossing synchronizer, data transition tracking loop, early-late gate tracking loop, sample-derivative timing recovery loop, Mueller and Muller synchronizer. However, in any conventional FSK correlation receiver, there must be an external synchronization and a timing recovery circuit for bit synchronization, clock recovery and timing recovery respectively. All of the above-mentioned circuits are complicated which increase overall die size and cost and therefore not suitable for application in low-cost wireless devices which requires acceptable performance at a fraction of the cost.

### SUMMARY OF INVENTION

Accordingly, one object of the present invention is to provide an algorithm for a FSK correlation receiver, capable of bit synchronization, clock recovery and timing recovery without an additional complex synchronization and a timing recovery circuit, instead, just with a simple circuit required. The cost and overall die size for such clock recovery and timing recovery functions in the FSK correlation receiver are significantly reduced.

To achieve these and other advantages and in accordance with the purpose of the invention, as embodied and broadly described herein, the invention provides an algorithm for time recovery in a frequency shift keying (FSK) receiver. The algorithm is described as followed. A training sequence is received from a transmitter. The training sequence is correlated with a predetermined reference signal to generate a corresponding correlation value. The status of timing in the FSK receiver is determined according to the generated correlation value, if the FSK receiver is in a timing-inaccurate status, an adjustment for the timing of the FSK receiver is determined in according to the correlation value.

In the above-mentioned algorithm for time recovery, the training sequence comprising a bit pattern, the bit pattern comprising a plurality of bits. Alternatively, each of the bits in the bit pattern is divided into a plurality of points, the points of each of the bits being used for the correlation with the predetermined reference signal in the FSK receiver and the correlation value being generated therefrom. In a preferred embodiment, the correlation value is generated by correlating the bit pattern with the predetermined reference signal with a correlation table. In the bit pattern above, a first bit and a last bit of the bits in the bit pattern are not used for the correlation in the FSK receiver.

In the above-mentioned algorithm for time recovery, the timing-inaccurate status of the FSK receiver includes a lag condition. In such a lag condition, the timing of the FSK receiver is speeded up with the adjustment determined in according to the correlation value to match the timing of the transmitter. In the above-mentioned algorithm for time recovery, the timing-inaccurate status of the FSK receiver further includes a lead condition. In such a lead condition, the timing of the FSK receiver is slowed down with the adjustment determined in according to the correlation value to match the timing of the transmitter.

To achieve these and other advantages and in accordance with the purpose of the invention, as embodied and broadly described herein, the invention provides an algorithm for time recovery in a frequency shift keying (FSK) receiver. The algorithm is described as followed. A training sequence is received from a transmitter. The training sequence includes a first bit pattern and a second bit pattern. The training sequence is detected to determining the first bit pattern and the second bit pattern being received. If the first bit pattern is received, correlating the first bit pattern with a first predetermined reference signal to generate a first correlation value. If the second bit pattern is received, correlating the second bit pattern with a second predetermined reference signal to generate a second correlation value. A status of timing in the FSK receiver is determined according to the generated first and second correlation values. If the FSK receiver is in a timing-inaccurate status, an adjustment for the timing of the FSK receiver is determined in according to the correlation value.

In the above-mentioned algorithm for time recovery, each of the first and second bit patterns includes a plurality of bits, each of bits being divided into a plurality of points, the points of each of the bits being used for the correlation. A first bit and a last bit of the bits in the first and second bit patterns are not used for the correlation in the FSK receiver.

Alternatively, the first and second correlation values are generated by respectively correlating the first bit pattern with the first predetermined reference signal and the second bit pattern with the second predetermined reference signal with a correlation table.

The timing-inaccurate status of the FSK receiver is determined by comparing the generated first correlation value and second correlation value, if the first correlation value is larger than the second correlation value, the FSK receiver is in a lag condition, if the first correlation value is smaller than the second correlation value, the FSK receiver is in a lead condition. If the FSK receiver is in the lag condition, the timing of the FSK receiver is speeded up with the adjustment. If the FSK receiver is in the lead condition, the timing of the FSK receiver is slowed down with the adjustment determined, to match the timing of the transmitter.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a diagram showing a 4-bit training sequence with a predetermined bit pattern transmitted by the transmitter and two 4-bit training sequences received by the receiver in two cases, one of which is a lag condition (Case I) and the other is a lead condition (Case 11); and

FIG. 2 is a schematic diagram of a preferred embodiment of a digital FSK correlation receiver of the invention.

### DETAILED DESCRIPTION

Reference will now be made in detail to the present preferred embodiments of the invention, examples of which are illustrated in the accompanying drawings. Wherever possible, the same reference numbers are used in the drawings and the description to refer to the same or like parts.

This invention provides an algorithm for time recovery in a digital frequency shift keying (FSK) receiver. The receiver correlated a received signal (the received signal is denoted as a training sequence or preamble, herein “training sequence”) with predetermined reference signals to generate corresponding correlation values. According to the generated correlation values, status of timing in the FSK receiver is determined. For example, if the FSK receiver is a timing-inaccurate status, such as a lag condition or a lead condition in timing, the timing is necessary to be adjusted to meet the exact timing of the transmitter. That is, a time recovery procedure is done by adjusting the timing in according to correlation values obtained by simply correlating the training sequence respectively with the reference signals. The clock cycle will be adjusted by a predetermined period to match the timing. The adjustment is determined as desired and applications. In the lag condition, for example, the timing of the FSK receiver is speeded up with the adjustment for matching the timing of the transmitter. In the lead condition, for example, the timing of the FSK receiver is slowed down with the adjustment for matching the timing of the transmitter.

The algorithm for time recovery in a digital frequency shift keying (FSK) receiver uses the same baseband demodulator of the receiver for demodulation, and an external synchronization and a timing recovery circuit used in a conventional art for bit synchronization, clock recovery and timing recovery is not necessary. With a very simple additional circuitry added in the FSK receiver, the FSK receiver can possess the function of synchronization, clock recovery and timing recovery. The algorithm can be applied in any wireless system such as radio frequency (RF) or broadband. The additional circuitry can be implemented by, for example, several registers and a simple processing circuitry for achieving a quick and accurate timing recovery. All the components are manufactured on a chip so that can reduce an overall space. The algorithm for time recovery is described hereafter in details.

In a frequency shift keying (FSK) wireless system incorporated the time recovery algorithm of the preferred embodiment of the invention, a transmitter sends out a programmable predetermined bit-length training sequence, for example, a training sequence with a 4-bit bit pattern. The training sequence includes a special bit pattern that is used for a receiver to determine any lag case or lead case occurred in the clock period. The receiver generating a positive correlation value Corr(+) and a negative correlation value Corr(−) by correlating the training sequence with the reference signals to determine if there is any lag or lead in the timing. In a preferred embodiment, a training sequence with a 4-bit-length pattern is enough for design and applications. The training sequence is, for example, “1100” and each bit is further divided into 100 points. As a result, the points are used to represent time in an accurate manner. The training sequence with 4-bit pattern is already accurate in determining the timing and performing a recovery for a balance in performance and cost. In another embodiment, a longer bit length can be used for higher performance; however, cost will be more. It depends on the applications desired for different requirements.

The present invention can automatically adjust the timing by correlating the training sequence and the reference signals to determine if there is the lag or lead situation occurred in the timing. The transmitter sends out a pair of signals, which includes a first correlation signal and a second correlation signal, within the training sequence. Each of the signals of the pair with the 4-bit in length provides a special bit pattern as a criterion for correlation by the receiver. The receiver correlates the bit pattern with a reference signal by, for example, a correlation table. The timing of the receiver and transmitter would be theoretically identical under an ideal condition. However, because of noises, one of which is an additive white Gaussian noise (AWGN) that exists in all wireless devices, the timing between the transmitter and receiver may be different from each other. Therefore, it is important to determine the amount of shiftings occurring in the system for correcting the timing.

The AWGN noise that affects every bit can be different but the overall effect can be averaged so that timing recovery can be achieved. It means that the training sequence with a 4-bit-length bit pattern can be “1100” or “0011”. Every 4 bits form a unit and the unit can be identically repeated to improve accuracy of the timing recovery, if necessary. The first bit and last bit of the bit pattern of the training sequence are ignored because they cannot fully capture the entire range due to their location limitation. Therefore only the middle 2 bits are compared for performing the timing recovery in the training sequence. In a longer bit length case for the training sequence, the first and last bits of the training sequence are ignored and the other bits can be used for the bit pattern. For example, if the bit length is 8, the first and eight bits of the bit pattern are ignored and the other 6 bits can be used for correlation and more accuracy being obtained.

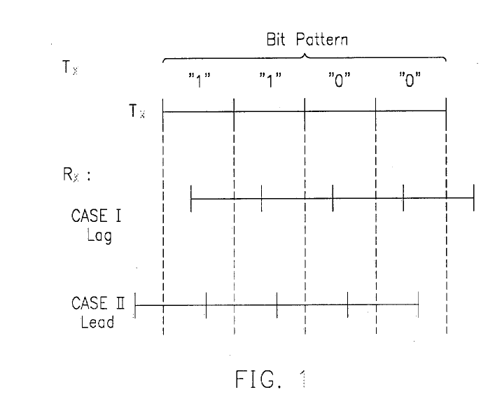

Referring to FIG. 1, which shows a 4-bit training sequence with a predetermined bit pattern transmitted by the transmitter and two 4-bit training sequences received by the receiver in two cases, one of which is a lag condition (Case I) and the other is a lead condition (Case II). These two conditions are all necessary to be adjusted to meet the exact timing of the transmitter, that is, a time recovery procedure is done by adjusting the timing in according to correlation values obtained by correlating the bit patterns of the training sequence respectively with reference signals, for example, one of which is a first reference signal with a frequency +ω t and a second reference signal with a frequency ω t, to respectively obtain a positive correlation value Corr(+) and a negative correlation value Corr(−) in the receiver. The receiver will detect the bit pattern of the training sequence when received and then determine the corresponding reference signal for correlation. In according to correlation of the bit pattern and the reference signal, the correlation value is then determined. The clock cycle will be adjusted by, for example, a 1/32 period to match the timing. For example, in the lag condition, the timing of the FSK receiver is speeded up with the 1/32 period for matching the timing of the transmitter. For example, in the lead condition the timing of the FSK receiver is slowed down with 1/32 period for matching the timing of the transmitter.

The algorithm of the timing recovery in the digital FSK correlation receiver of a preferred embodiment of the invention is described as followed. Firstly, the transmitter sends out a predefined special bit pattern at a correct timing. The timing between each bit is divided into points which control an over-sampling rate. In a preferred embodiment, 100 points are provided for each bit. In an alternative embodiment, points more than 100 for dividing each bit can be used for more accuracy. The sampling for correlating the received training sequence and reference training signals is only performed at each bit but not at each point. The positive correlation value Corr(+) and the negative correlation value Corr(−) are temporarily recorded after performing the correlation. The value of each bit of each signal will be added together. In a lag situation, the total of the positive correlation value Corr(+) is larger than the negative correlation value Corr(−), and oppositely in a lead situation the total of the positive correlation value Corr(+) value is smaller than the negative correlation value Corr(−) value. An adjustment value for the lag or lead situation is determined by design required, for example, 1/32 period to match the timing. If necessary, more bit patterns of the training sequence can be sent by the transmitter and adjustments therefrom are used to adjust the timing until there is no lag or lead situation occurred. That is, adjusted with the adjustment value, the difference between the positive correlation value Corr(+) and the negative correlation value Corr (−) for following received signals can be almost equal. Obviously if there is no lag or lead situation occurred in the beginning, that is the difference between the positive correlation value Corr(+) and the negative correlation value Corr(−) is 0, no adjustment is required to be made.

In this embodiment, a 4-bit training sequence “1100” is used, for example. A table showing the correlation values obtained at each bit is shown in Table 1.

TABLE 1

| Training Sequence | | 1 | 1 | 0 | 0 | SUM |
|---|---|---|---|---|---|---|
| Case I. Lag | Corr (+) | X | 20 | 120 | X | 140 |
| | Corr (−) | X | 100 | 0 | X | 100 |
| Case II. Lead | Corr (+) | X | 0 | 100 | X | 100 |
| | Corr (−) | X | 120 | 20 | X | 140 |

For a first bit “1” and a last bit “0”, obtained correlation values are ignored and use an “X” to represent, which mean “Don't Care”. Middle two bits of the bit pattern the training sequence is used for determining the timing by comparing summation of all of the positive correlation value Corr(+) and the negative correlation value Corr(−) respectively received by the receiver. Table 1 illustrates two sets of correlation values of the receiver for a lag situation (case I) and a lead (case II.) situation. Two correlation values for the two middle bits are respectively added together and then two summations are generated. In case I, the summation of the positive correlation value Corr(+) is 140 and the summation of the negative correlation value Corr(−) is 100. Therefore, summation of the positive correlation value Corr(+) is larger than summation of the negative correlation value Corr(−). That means that it is a lag situation. The lag situation means that the receiver is slower in timing than the transmitter and the entire timing needs to be shifted to the left. In the lead situation (case 2), the total of the positive correlation values Corr(+) is 100 and the total of the negative correlation values Corr(−) is 140 therefore the positive correlation value Corr (+) is smaller than the negative correlation value Corr(−) and it is a lead situation. The lead situation means that the receiver is faster in timing than the transmitter and the entire timing needs to be shifted to the right.

If accuracy of the timing recovery is desired to improve, the training sequence can be identically repeated to form a longer training sequence with more units if noise is high. Again a unit is a special pattern of 4 bits. If a training sequence longer than 4 bits is used, only the first and last bits of the entire training sequence are ignored and not every first and last bits of each unit. However if the bit length of the training sequence is increased, the processing ability needs to be corresponding increased. This will in fact increase cost. Alternatively, the accuracy of this algorithm can be increased by increasing the over-sampling rate, that is the division of bit into points. In this embodiment, each bit is divided into 100 points but, if desired, the bit can be divided into infinitely minuscule parts for improved accuracy. It is to be noted that the increase in bit length of training sequence is a much more effective method to increase accuracy. However increasing the sampling rate does not necessarily increase the cost because it can be adjusted by a, for example, phase lock loop (PLL) circuitry.

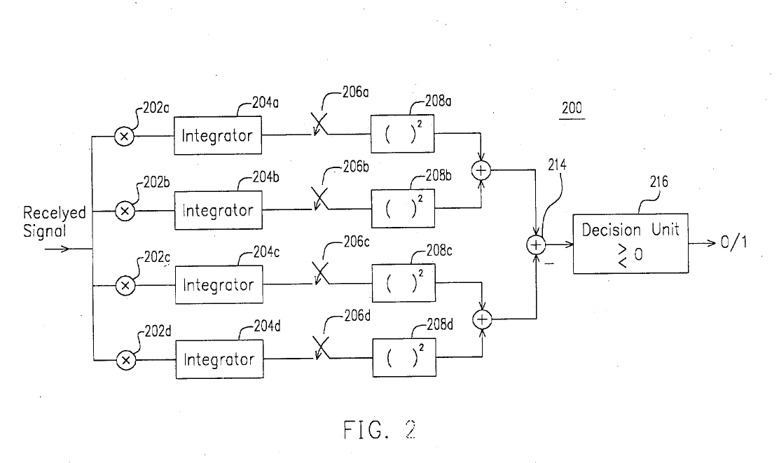

FIG. 2 is a schematic diagram of a preferred embodiment of a digital FSK correlation receiver of the invention. In the embodiment, a training sequence with 4-bit pattern is used and only two bits of which are calculated for the time recovery procedure. The receiver 200 includes four demodulators 202a, 202b, 202c and 202d, integrators 204a, 204b, 204c and 204d, switches 206a, 206b, 206c and 206d, sampling devices 208a, 208b, 208c and 208d, a digital comparator 214 and a decision unit 216. A pair of correlation signals for a predefined training sequence, is sequentially received from the transmitter (not shown) by the FSK correlation receiver 200. A first correlation signal is applied to the demodulators 202a and 202b and is multiplied by the signals with 4 different frequencies by demodulators 202a, 202b, 202c and 202d which shifts the phase of the signals. These signals output from the demodulators 202a, 202b, 202c and 202d are then respectively sent to integrators 204a, 204b, 204c and 204d by turning on the switches 206a, 206b, 206c and 206d during a bit period for converting into digital signals. The two signals are simultaneously sampled at every single point by the sampling devices 208a and 208b and results are sent to the an adder 210 for the positive correlation value Corr(+). The two signals are simultaneously sampled at every single point by the sampling devices 208b and 208d and results are sent to the an adder 212 for the negative correlation value Corr(−).

The positive correlation value Corr(+) and the negative correlation value Corr(−) are compared by a digital comparator 220, including a digital comparator 214 for subtracting the negative correlation value Corr(−) from the positive correlation value Corr(+); and a decision unit 216 for determining the result from the digital comparator 214 is positive or negative. If the result from the digital comparator 214 is positive, the decision unit 216 outputs 1, and if the result from the digital comparator 214 is negative, the decision unit 216 outputs 0. The result of the digital comparator 220 is the correlation value at every bit. The actual implementation of the FSK correlation receiver can be done in an analog system.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. An algorithm for time recovery in a frequency shift keying (FSK) receiver, the algorithm comprising:
receiving a training sequence from a transmitter;
correlating the training sequence with a predetermined reference signal to generate a corresponding correlation value; and
determining status of timing in the FSK receiver according to the generated correlation value, if the FSK receiver is in a timing-inaccurate status, an adjustment for the timing of the FSK receiver is determined in according to the correlation value.

2. The algorithm for time recovery of claim 1, the training sequence comprising a bit pattern, the bit pattern comprising a plurality of bits.

3. The algorithm for time recovery of claim 2, each of the bits in the bit pattern being divided into a plurality of points, the points of each of the bits being used for the correlation with the predetermined reference signal in the FSK receiver and the correlation value being generated therefrom.

4. The algorithm for time recovery of claim 3, the correlation value being generated by correlating the bit pattern with the predetermined reference signal with a correlation table.

5. The algorithm for time recovery of claim 2, a first bit and a last bit of the bits in the bit pattern not being used for the correlation in the FSK receiver.

6. The algorithm for time recovery of claim 1, the timing-inaccurate status of the FSK receiver comprising a lag condition, the timing of the FSK receiver is speeded up with the adjustment determined in according to the correlation value to match the timing of the transmitter.

7. The algorithm for time recovery of claim 1, the timing-inaccurate status of the FSK receiver comprising a lead condition, the timing of the FSK receiver is slowed down with the adjustment determined in according to the correlation value to match the timing of the transmitter.

8. A frequency shift keying (FSK) receiver using the algorithm for time recovery as claimed in claim 1.

9. An algorithm for time recovery in a frequency shift keying (FSK) receiver, the algorithm comprising:
receiving a training sequence from a transmitter, the training sequence comprising a first bit pattern and a second bit pattern;
detecting the training sequence to determining the first bit pattern and the second bit pattern being received, if the first bit pattern being received, correlating the first bit pattern with a first predetermined reference signal to generate a first correlation value, if the second bit pattern being received, correlating the second bit pattern with a second predetermined reference signal to generate a second correlation value; and
determining status of timing in the FSK receiver according to the generated first and second correlation values, if the FSK receiver is in a timing-inaccurate status, an adjustment for the timing of the FSK receiver is determined in according to the correlation value.

10. The algorithm for time recovery of claim 9, each of the first and second bit patterns comprising a plurality of bits, each of bits being divided into a plurality of points, the points of each of the bits being used for the correlation.

11. The algorithm for time recovery of claim 10, the first and second correlation values being generated by respectively correlating the first bit pattern with the first predetermined reference signal and the second bit pattern with the second predetermined reference signal with a correlation table.

12. The algorithm for time recovery of claim 10, a first bit and a last bit of the bits in the first and second bit patterns not being used for the correlation in the FSK receiver.

13. The algorithm for time recovery of claim 9, the timing-inaccurate status of the FSK receiver being determined by comparing the generated first correlation value and second correlation value, if the first correlation value is larger than the second correlation value, the FSK receiver is in a lag condition, if the first correlation value is smaller than the second correlation value, the FSK receiver is in a lead condition.

14. The algorithm for time recovery of claim 13, if the FSK receiver being in the lag condition, the timing of the FSK receiver is speeded up with the adjustment, if the FSK receiver being in the lead condition, the timing of the FSK receiver is slowed down with the adjustment determined, to match the timing of the transmitter.

15. A frequency shift keying (FSK) receiver using the algorithm for time recovery as claimed in claim 9.
